(19) United States
(12) Patent Application Publication
(10) Pub. No.: US 2007/0054463 A1
(43) Pub. Date: Mar. 8, 2007

(54) Method for forming spacers between bitlines in virtual ground memory array and related structure

(75) Inventor: Hiroyuki Ogawa, Tokyo (JP)

Correspondence Address: FARJAMI & FARJAMI LLP, Suite 360, 26522 La Alameda Avenue, Mission Viejo, CA, 92691, US

(73) Assignee: SPANSION LLC

(21) Appl. No.: 11/227,749

(22) Filed: Sep. 15, 2005

(51) Int. Cl. H01L 21/76

(52) U.S. Cl. 438/400

(57) ABSTRACT

According to one exemplary embodiment, a method of fabricating a virtual ground memory array, which includes bitlines situated in a substrate, includes forming at least one recess in the substrate between two adjacent bitlines, where the at least one recess is situated in a bitline contact region of the virtual ground memory array, and where the at least one recess defines sidewalls and a bottom surface in the substrate. The step of forming the at least one recess includes using hard mask segments as a mask, where each of the hard mask segments is situated over a bitline. The method further includes forming a spacer in the at least one recess, where the spacer reduces bitline-to-bitline leakage between the adjacent bitlines. The method further includes forming stacked gate structures before forming the at least one recess, where each stacked gate structure is situated over and perpendicular to the bitlines.

### 1. TECHNICAL FIELD

The present invention is generally in the field of semiconductor devices. More particularly, the invention is in the field of fabrication of memory arrays.

### 2. BACKGROUND ART

A virtual ground memory array architecture is often used for flash memory arrays, such as flash memory arrays using floating gate memory cells, or flash memory arrays using memory cells capable of storing two independent bits, such as Advanced Micro Devices' (AMD) MirrorBit™ memory cells. A typical virtual ground flash memory array includes bitlines, which are formed in a silicon substrate, and stacked gate structures, which are formed over and perpendicular to the bitlines. In a virtual ground floating gate flash memory array, each stacked gate structure can include a wordline situated over an Oxide-Nitride-Oxide (ONO) stack, which is situated over a number of floating gates.

However, in conventional memory arrays utilizing a virtual ground architecture, an isolation region is not formed between each bitline. As a result, bitline-to-bitline leakage can undesirably increase as the conventional virtual ground memory array is scaled down. Also, after the stacked gate structure has been etched during formation of the conventional virtual ground memory array, silicide cannot be formed on the bitlines to reduce bitline resistance, since silicide would also form over exposed silicon situated between bitlines and, thereby, cause the bitlines to short together.

Further, in the conventional virtual ground memory, bitline contact misalignment can cause leakage current to occur between the bitline and undoped silicon areas situated adjacent to the bitlines, thereby reducing the effectiveness of the bitline contact. To prevent bitline contact misalignment by ensuring that the bitline contact is formed over the bitline, an additional dopant implant has been utilized to increase the size of the bitline diffusion region after the contact has been etched. However, the increased bitline diffusion region also increases bitline-to-bitline leakage by decreasing the distance between bitlines.

Thus, there is a need in the art for an effective method for reducing bitline-to-bitline leakage and bitline resistance in a virtual ground memory array, such as a virtual ground flash memory array.

### SUMMARY

The present invention is directed to a method for forming spacers between bitlines in a virtual ground memory array and related structure. The present invention addresses and resolves the need in the art for an effective method for reducing bitline-to-bitline leakage and bitline resistance in a virtual ground memory array, such as a virtual ground flash memory array.

According to one exemplary embodiment, a method of fabricating a virtual ground memory array, which includes a number of bitlines situated in a substrate, includes forming at least one recess in the substrate between two adjacent bitlines, where the at least one recess is formed in a bitline contact region of the virtual ground memory array, and where the at least one recess defines sidewalls and a bottom surface in the substrate. The virtual ground memory array can be a virtual ground flash memory array, such as a virtual ground floating gate flash memory array, for example. The recess can have a depth of approximately 2000.0 Angstroms, for example. The step of forming the at least one recess includes using hard mask segments as a mask, where each of the hard mask segments is situated over one of the bitlines. For example, the hard mask segments may be high density plasma oxide. A layer of tunnel oxide may be situated between the hard mask segments and the bitlines, for example.

According to this embodiment, the method further includes forming a spacer in the at least one recess in the substrate, where the spacer reduces bitline-to-bitline leakage between the two adjacent bitlines. The step of forming the spacer can include forming an oxide liner on the sidewalls and bottom surface of the at least one recess and forming a silicon nitride segment on the oxide liner, for example. The method further includes forming stacked gate structures before forming the at least one recess, where each of the stacked gate structures is situated over and perpendicular to the bitlines. Each of the stacked gate structures includes a wordline, where the wordline is situated over the hard mask segments. According to one embodiment, the invention is a structure that is achieved by utilizing the above-described method. Other features and advantages of the present invention will become more readily apparent to those of ordinary skill in the art after reviewing the following detailed description and accompanying drawings.

### BRIEF DESCRIPTION OF THE DRAWINGS

FIG. 1 illustrates a top view of some of the features of a virtual ground memory array in an intermediate stage of fabrication, formed in accordance with one embodiment of the present invention.

FIG. 2 shows a cross-sectional view of structure 100 along line A-A in FIG. 1.

FIG. 3 shows a flowchart illustrating the steps taken to implement an embodiment of the present invention.

FIG. 4A illustrates a cross-sectional view, which includes a portion of a wafer processed according to an embodiment of the invention, corresponding to an intermediate step in the flowchart in FIG. 3.

FIG. 4B illustrates a cross-sectional view, which includes a portion of a wafer processed according to an embodiment of the invention, corresponding to an intermediate step in the flowchart in FIG. 3.

FIG. 4C illustrates a cross-sectional view, which includes a portion of a wafer processed according to an embodiment of the invention, corresponding to an intermediate step in the flowchart in FIG. 3.

### DETAILED DESCRIPTION OF THE INVENTION

The present invention is directed to a method for forming spacers between bitlines in a virtual ground memory array and related structure. The following description contains specific information pertaining to the implementation of the present invention. One skilled in the art will recognize that the present invention may be implemented in a manner different from that specifically discussed in the present application. Moreover, some of the specific details of the invention are not discussed in order not to obscure the invention.

The drawings in the present application and their accompanying detailed description are directed to merely exemplary embodiments of the invention. To maintain brevity, other embodiments of the present invention are not specifically described in the present application and are not specifically illustrated by the present drawings. It should be borne in mind that, unless noted otherwise, like or corresponding elements among the figures may be indicated by like or corresponding reference numerals.

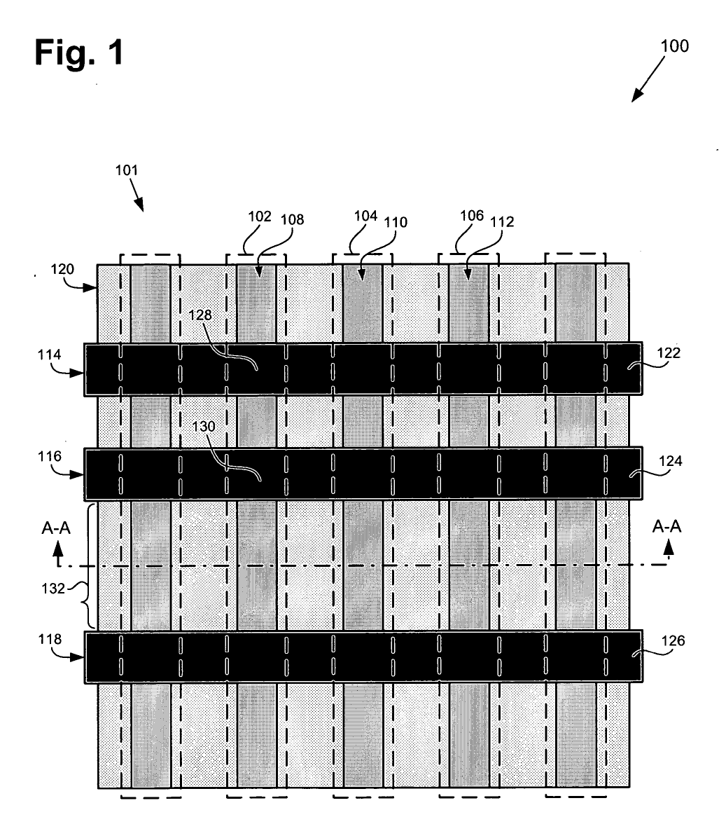

FIG. 1 shows a top view of an exemplary virtual ground memory array in an intermediate stage of fabrication in accordance with one embodiment of the present invention. Structure 100 includes virtual ground memory array 101, which is situated on a substrate (not shown in FIG. 1) and which includes bitlines 102, 104, and 106, hard mask segments 108, 110, and 112, stacked gate structures 114, 116, and 118, dielectric layer 120, wordlines 122, 124, and 126, memory cells 128 and 130, and bitline contact region 132. Virtual ground memory array 101 can be a virtual ground flash memory array, such as a virtual ground floating gate flash memory array, in an intermediate stage of fabrication. In one embodiment, virtual ground memory array 101 can be virtual ground flash memory array comprising memory cells capable of storing two independent bits (i.e. two-bit memory cells), such as AMD's MirrorBit™ memory cells. It is noted that in FIG. 1, only bitlines 102, 104, and 106, hard mask segments 108, 110, and 112, and memory cells 128 and 130 are specifically discussed herein to preserve brevity.

As shown in FIG. 1, stacked gate structures 114, 116, and 118 are situated over and perpendicular to bitlines 102, 104, and 106. Stacked gate structures 114, 116, and 118 include wordlines 122, 124, and 126, respectively, which are situated over segments of a first layer of polycrystalline silicon (poly 1) (not shown in FIG. 1). The segments of poly 1 are situated over dielectric layer 120, which can comprise a layer of tunnel oxide or other appropriate dielectric material. In one embodiment, dielectric layer 120 can comprise an ONO stack. Wordlines 122, 124, and 126 can each comprise segments of a second layer of polycrystalline silicon (poly 2). Stacked gate structures 114, 116, and 118 can also include an anti-reflective coating layer (not shown in FIG. 1) situated over wordlines 122, 124, and 126. Stacked gate structures 114, 116, and 118 can be formed in a stacked gate etch process as known in the art.

Bitlines 102, 104, and 106 are situated in a silicon substrate (not shown in FIG. 1) and can comprise arsenic or other appropriate dopant. Also shown in FIG. 1, hard mask segments 108, 110, and 112 are situated over dielectric layer 120 and over respective bitlines 102, 104, and 106. Hard mask segments 108, 110, and 112 are also situated under wordlines 122, 124, and 126 and between poly 1 segments (not shown in FIG. 1) in respective stacked gate structures 114, 116, and 118. In the present embodiment, hard mask segments 102, 104, and 106 can comprise high density plasma (HDP) oxide. In other embodiments, hard mask segments 102, 104, and 106 can comprise tetraethylorthosilicate (TEOS) oxide or other appropriate oxide.

Further shown in FIG. 1, memory cell 128 is situated at the intersection of wordline 122 and bitline 102 and memory cell 130 is situated at the intersection of wordline 124 and bitline 102. In the present embodiment, memory cells 128 and 130 can be floating gate memory cells, such as floating gate flash memory cells. In one embodiment, memory cells 128 and 130 can be two-bit memory cells, such as AMD's MirrorBit™ memory cells. Stacked gate structures 114, 116, and 118 each comprise a row of memory cells, which are situated at the intersection of each wordline and each bitline. Also shown in FIG. 1, bitline contact region 132 is situated in virtual ground memory array 101 between wordlines 124 and 126, which are situated in respective stacked gate structures 116 and 118.

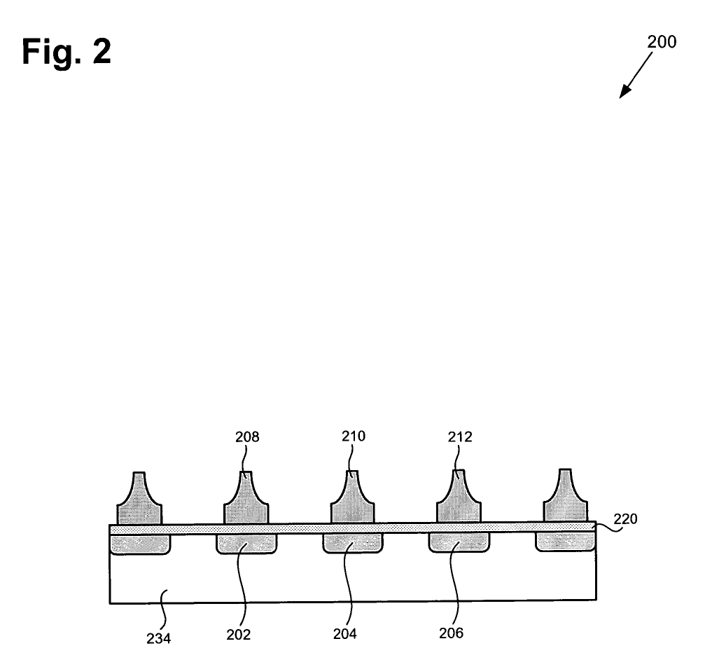

Referring to FIG. 2, structure 200 in FIG. 2 corresponds to a cross-sectional view of structure 100 along line A-A in FIG. 1. In particular, bitlines 202, 204, and 206, hard mask segments 208, 210, and 212, and dielectric layer 220 in FIG. 2 correspond, respectively, to bitlines 102, 104, and 106, hard mask segments 108, 110, and 112, and dielectric layer 120 in FIG. 2. Structure 200 can be formed in bitline contact region 132 of virtual ground memory array 101 in FIG. 1 during formation of stacked gate structures 114, 116, and 118 in a stacked gate etch process.

As shown in FIG. 2, bitlines 202, 204, and 206 are situated in silicon substrate 234. Also shown in FIG. 2, dielectric layer 220 is situated over bitlines 202, 204, and 206 on silicon substrate 234 and hard mask segments 208, 210, and 212 are situated on dielectric layer 220 and over respective bitlines 208, 210, and 212. In subsequent process steps in the present invention, a recess will be formed between adjacent bitlines (e.g. between bitlines 202 and 204 and bitlines 204 and 206) in structure 200 using hard mask segments 208, 210, and 212 as a mask and a spacer will be formed in each recess.

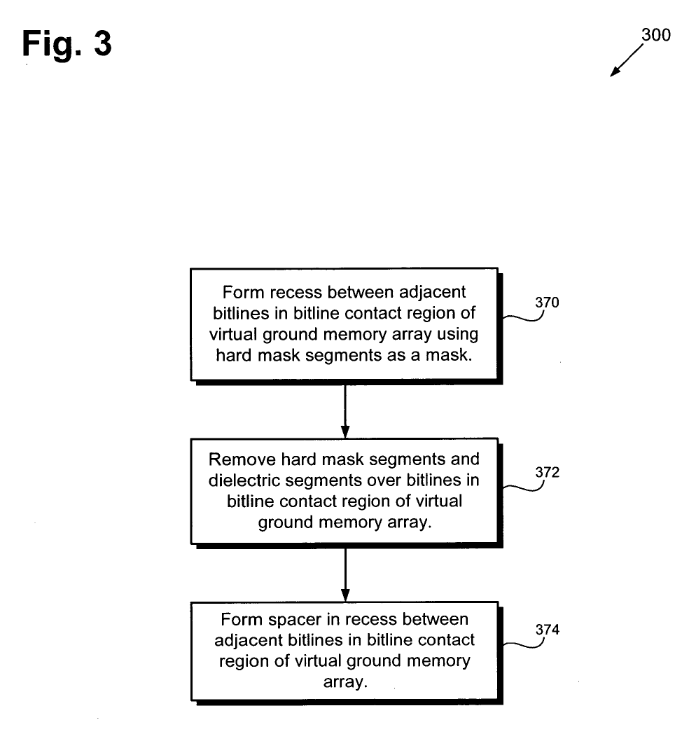

FIG. 3 shows a flowchart illustrating an exemplary method according to an embodiment of the present invention. Certain details and features have been left out of flowchart 300 that are apparent to a person of ordinary skill in the art. For example, a step may consist of one or more substeps or may involve specialized equipment, as known in the art. While steps 370 through 374 indicated in flowchart 300 are sufficient to describe one embodiment of the present invention, other embodiments of the invention may use steps different from those shown in flowchart 300. It is noted that the processing steps shown in flowchart 300 are performed on a wafer, which, prior to step 370, includes structure 200 shown in FIG. 2, which is a cross-sectional view of structure 100 along line A-A in FIG. 1.

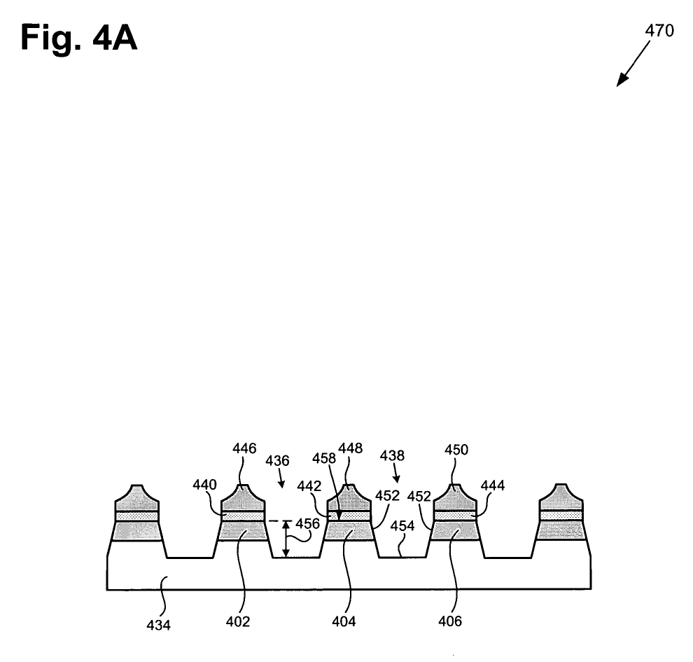

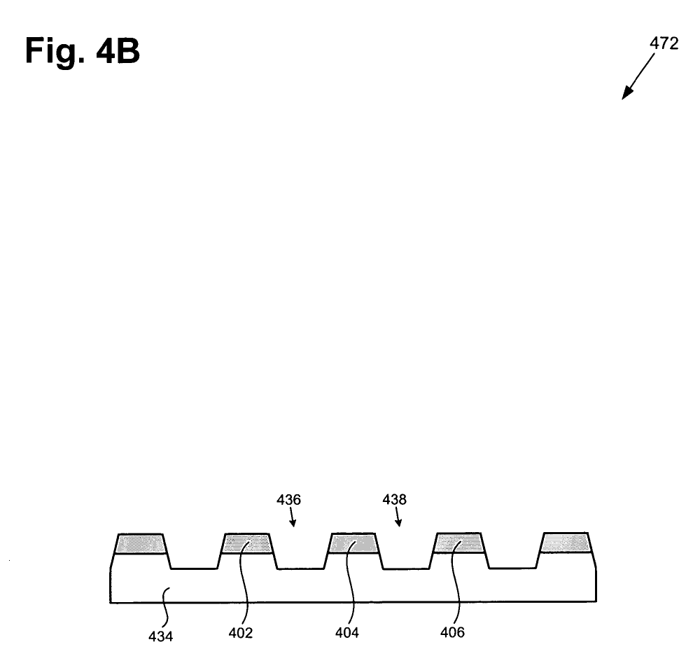

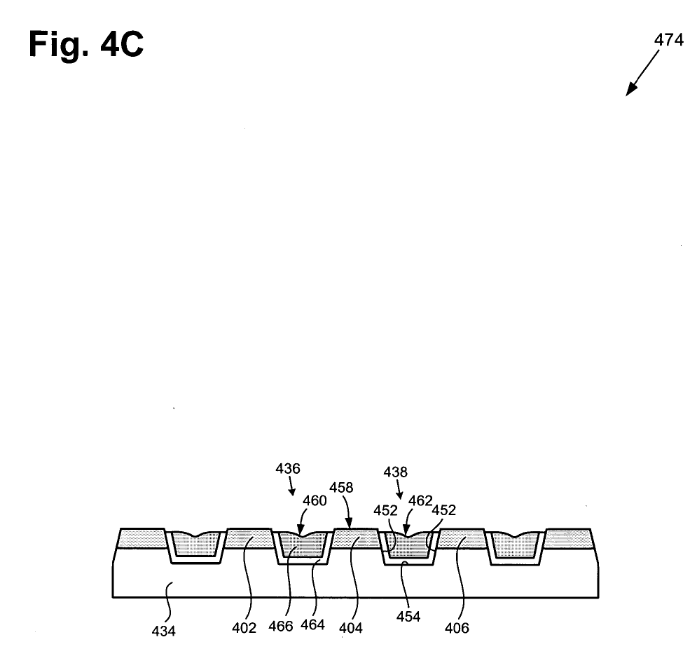

Referring to FIGS. 4A, 4B, and 4C, each of structures 470, 472, and 474 illustrates the result of performing steps 370, 372, and 374, respectively, of flowchart 300 in FIG. 3. For example, structure 470 shows the result of performing step 370, structure 472 shows the result of performing step 372, and so forth.

Referring now to step 370 in FIG. 3 and structure 470 in FIG. 4A, at step 370 of flowchart 300, recess 436 is formed between bitlines 402 and 404 and recess 438 is formed between bitlines 404 and 406 in bitline contact region 132 of virtual ground memory array 101 in FIG. 1. Bitlines 402, 404, and 406 and silicon substrate 434 in FIG. 4 correspond, respectively, to bitlines 202, 204, and 206 and silicon substrate 234 in FIG. 2. As shown in FIG. 4A, bitlines 402, 404, and 406 are situated in silicon substrate 434, and dielectric segments 440, 442, and 444 are situated over bitlines 402, 404, and 406, respectively. Dielectric segments 440, 442, and 444 can comprise tunnel oxide and can be formed by etching dielectric layer 220 in a plasma etch process, for example, during formation of respective recesses 436 and 438. In one embodiment, dielectric segments 440, 442, and 444 can each comprise an ONO stack segment.

Also shown in FIG. 4A, hard mask segments 446, 448, and 450 are situated over dielectric segments 440, 442, and 444. Hard mask segments 446, 448, and 450 are substantially similar in width and composition to hard mask segments 202, 204, and 206 in FIG. 2. However, hard mask segments 446, 448, and 450 have a reduced height compared to respective hard mask segments 202, 204, and 206 as a result of the etching process used to form recesses 436 and 438. Further shown in FIG. 4A, recess 436 is situated in silicon substrate 434 between bitlines 402 and 404 and recess 438 is situated in silicon substrate 434 between bitlines 404 and 406. Recesses 436 and 438 can be formed by using hard mask segments 208, 210, and 212 as a mask such that recess 436 is aligned between adjacent bitlines 402 and 404 and recess 438 is aligned between adjacent bitlines 404 and 406.

The portions of dielectric layer 220 in FIG. 2 and silicon substrate 234 that are not protected by hard mask segments 208, 210, and 212 can be etched using a plasma etch process or other appropriate etch process. Recesses 436 and 438 define sidewalls 452 and bottom surface 454 in silicon substrate 234 and has depth 456, which corresponds to the distance between bottom surface 454 and top surface 458 of silicon substrate 434. For example, depth 456 of recesses 436 and 438 can be approximately 2000.0 Angstroms. However, depth 456 may also be greater or less than 2000.0 Angstroms. It is noted that in FIG. 4A, only recesses 436 and 438, dielectric segments 440, 442, and 444, and hard mask segments 446, 448, and 450 are specifically discussed herein to preserve brevity. The result of step 370 of flowchart 300 is illustrated by structure 470 in FIG. 4A.

Referring to step 372 in FIG. 3 and structure 472 in FIG. 4B, at step 372 of flowchart 300, hard mask segments 446, 448, and 450 (FIG. 4A) and dielectric segments 440, 442, and 444 (FIG. 4B) are removed over respective bitlines 402, 404, and 406. Hard mask segments 446, 448, and 450 (FIG. 4B) and dielectric segments 440, 442, and 444 (FIG. 4B) can be removed by using a wet etch process or other appropriate etch process. The result of step 372 of flowchart 300 is illustrated by structure 472 in FIG. 4B.

Referring to step 374 in FIG. 3 and structure 474 in FIG. 4C, at step 374 of flowchart 300, spacer 460 is formed in recess 436 between bitlines 402 and 404 and spacer 438 is formed in recess 438 between bitlines 404 and 406. As shown in FIG. 4C, spacers 460 and 462 are situated in respective recesses 436 and 438. In the present embodiment, spacers 460 and 462 can comprise oxide liner 464, which is situated on sidewalls 452 and bottom surface 454. Oxide liner 464 can have a thickness of between approximately 100.0 Angstroms and 500.0 Angstroms, for example. Spacers 460 and 464 can further comprise silicon nitride segment 466, which is situated on oxide liner 464. Silicon nitride segment 466 can have a thickness of between approximately 500.0 Angstroms and 1000.0 Angstroms, for example.

Spacers 460 and 462 can be formed by depositing a layer of silicon oxide over structure 472 in FIG. 4B and appropriately etching back the layer of silicon oxide to form oxide liner 464. A layer of silicon nitride can then be deposited over silicon substrate 434 and oxide liner 464 and appropriately etched back to form silicon nitride segment 466 on oxide liner 464. In one embodiment, spacers 460 and 462 may comprise a layer of silicon oxide, which can be deposited and etched back in respective recesses 436 and 438. The result of step 374 of flowchart 300 is illustrated by structure 474 in FIG. 4C.

By forming a recess between adjacent bitlines and forming a spacer in the recess, the present invention advantageously achieves a virtual ground memory array, such as a virtual ground flash memory array, having significantly reduced bitline-to-bitline leakage compared to a conventional virtual ground memory array. Also, by forming spacers comprising an appropriately dielectric material, such as silicon oxide and silicon nitride, silicide, such as cobalt silicide, can be formed over the bitlines, such as bitlines 402, 404, and 406, to reduce bitline resistance. In contrast, in a conventional virtual ground memory array, silicide cannot be formed on the bitlines without also forming silicide on the silicon substrate situated between the bitlines, which causes the bitlines to short together. Thus, by allowing silicide to be formed over the bitlines in a virtual ground memory array, the present invention advantageously achieves a virtual ground memory array having reduced bitline resistance compared to a conventional virtual ground memory array.

Furthermore, by forming a recess between adjacent bitlines in a bitline contact region of a virtual ground memory array and forming a spacer in the recess, the present invention prevents allows a portion of a misaligned bitline contact to form on the spacer. As a result, the present invention achieves a virtual ground memory array that advantageously prevents undesirable leakage from occurring in the silicon substrate as a result of a misaligned bitline contact.

From the above description of exemplary embodiments of the invention it is manifest that various techniques can be used for implementing the concepts of the present invention without departing from its scope. Moreover, while the invention has been described with specific reference to certain embodiments, a person of ordinary skill in the art would recognize that changes could be made in form and detail without departing from the spirit and the scope of the invention. The described exemplary embodiments are to be considered in all respects as illustrative and not restrictive. It should also be understood that the invention is not limited to the particular exemplary embodiments described herein, but is capable of many rearrangements, modifications, and substitutions without departing from the scope of the invention.

Thus, a method for forming spacers between bitlines in a virtual ground memory array and related structure have been described.

1. A method for fabricating a virtual ground memory array, said virtual ground memory array comprising a plurality of bitlines situated in a substrate, said method comprising steps of:
forming at least one recess in said substrate between two adjacent bitlines in said plurality of bitlines, said at least one recess being situated in a bitline contact region of said virtual ground memory array, said at least one recess defining sidewalls and a bottom surface in said substrate;
forming a spacer in said recess;
wherein said spacer reduces bitline-to-bitline leakage between said two adjacent bitlines.

2. The method of claim 1 wherein said step of forming said at least one recess comprises using a plurality of hard mask segments as a mask, wherein each of said plurality of hard mask segments is situated over one of said plurality of bitlines.

3. The method of claim 2 wherein a layer of tunnel oxide is situated between said plurality of hard mask segments and said plurality of bitlines.

4. The method of claim 1 wherein said step of forming said spacer comprises steps of:
forming an oxide liner on said sidewalls and said bottom surface of said at least one recess;
forming a silicon nitride segment on said oxide liner.

5. The method of claim 2 further comprising a step of forming a plurality of stacked gate structures prior to said step of forming said at least one recess, wherein each of said plurality of stacked gate structures is situated over and perpendicular to said plurality of bitlines.

6. The method of claim 5 wherein each of said plurality of stacked gate structures comprises a wordline, wherein said wordline is situated over said plurality of hard mask segments.

7. The method of claim 1 wherein said virtual ground memory array is a virtual ground flash memory array.

8. The method of claim 7 wherein said virtual ground flash memory array is a virtual ground floating gate flash memory array.

9. The method of claim 2 wherein said plurality of hard mask segments comprise high density plasma oxide.

10. The method of claim 1 wherein said at least one recess has a depth of approximately 2000.0 Angstroms.

11. A virtual ground memory array comprising:
a plurality of bitlines situated in a substrate;
a plurality of recesses situated in a bitline contact region of said virtual ground memory array, each of said plurality of recesses being situated between two adjacent bitlines in said plurality of bitline, said each of said plurality of recesses defining sidewalls and a bottom surface in said substrate;
a spacer situated in said each of said plurality of recesses;
wherein said spacer decreases bitline-to-bitline leakage.

12. The virtual ground memory array of claim 11 wherein said spacer comprises an oxide liner situated on said sidewalls and said bottom surface of said each of said recesses.

13. The virtual ground memory array of claim 12 wherein said spacer further comprises a silicon nitride segment situated on said oxide liner.

14. The virtual ground memory array of claim 11 further comprising a plurality of stacked gate structures situated over and perpendicular to said plurality of bitlines, wherein said bitline contact region is situated between two of said plurality of stacked gate structures.

15. The virtual ground memory array of claim 11 wherein each of said stacked gate structures comprises a wordline, wherein said wordline is situated over a plurality of hard mask segments.

16. The virtual ground memory array of claim 15 wherein said plurality of hard mask segments comprise high density plasma oxide.

17. The virtual ground memory array of claim 11 wherein said virtual ground memory array is a virtual ground flash memory array.

18. The virtual ground memory array of claim 17 wherein said virtual ground floating gate memory array is a virtual ground floating gate flash memory array.

19. The virtual ground memory array of claim 11 where a depth of said each of said plurality of recesses is approximately 2000.0 Angstroms.

20. The virtual ground memory array of claim 13 wherein said silicon nitride segment has a thickness of between approximately 500.0 Angstroms and 1000.0 Angstroms.
